(19) United States
(12) Patent Application Publication
(10) Pub. No.: US 2023/0078225 A1
(43) Pub. Date: Mar. 16, 2023

(54) FLIP-CHIP LIGHT EMITTING DIODE (LED) DEVICE

(71) Applicant: XIAMEN SAN'AN OPTOELECTRONICS CO., LTD., Fujian Province (CN)

(72) Inventors: Zhanggen XIA, Fujian (CN); Peng LIU, Fujian Province (CN); Min HUANG, Fujian (CN); Guangyao WU, Fujian Province (CN); Ling-Yuan HONG, Fujian (CN); Chung-Ying CHANG, Fujian Province (CN)

(73) Assignee: XIAMEN SAN'AN OPTOELECTRONICS CO., LTD., Fujian Province (CN)

(21) Appl. No.: 17/942,066

(22) Filed: Sep. 9, 2022

(30) Foreign Application Priority Data
Sep. 13, 2021 (CN) 202111070808.3
Sep. 14, 2021 (CN) 202111076880.7

(51) Int. Cl. H01L 33/38; H01L 33/62; H01L 23/00

(52) U.S. Cl. CPC H01L 33/382; H01L 33/62; H01L 24/05; H01L 24/06; H01L 2224/05553; H01L 2224/05572; H01L 2224/05573; H01L 2224/0612; H01L 33/20

(57) ABSTRACT

A flip-chip LED device includes an epitaxial structure, a first contact electrode, and a second contact electrode. The second contact electrode is disposed on the epitaxial structure and extending toward the first contact electrode. The second contact electrode includes a first curved extension, a second curved extension, a connecting portion, a first straight extension, and a second straight extension. The connecting portion is connected to the first curved extension and to the second curved extension. The first straight extension is connected to the first curved extension. The second straight extension is connected to the second curved extension.

### CROSS-REFERENCE TO RELATED APPLICATION

This application claims priority to Chinese Invention Patent Application No. 202111076880.7, filed on Sep. 14, 2021, and Chinese Invention Patent Application No. 202111070808.3 filed on Sep. 13, 2021.

### FIELD

The disclosure relates to a light emitting diode (LED) device, and more particularly to a flip-chip LED device.

### BACKGROUND

A conventional Light Emitting Diode (LED) is a semiconductor device that uses energy released during carrier recombination to generate light. LEDs have several advantages over traditional lighting technology such as low energy consumption, uniform color reproduction, long service life, fast response time, and small size. LEDs are environmentally friendly, and have been widely employed in lighting, visible light communication (VLC) and light emitting display devices. LEDs may be categorized according to its package structure into conventional chip (epi-up), flip-chip, and vertical-type. In particular, for the flip-chip LED, the chip is inverted in the LED housing when compared to conventional LEDs, and the light is emitted from the sapphire side so that the electrodes may be attached to a substrate which has an increased heat dissipation effect.

However, there are still some drawbacks in current flip-chip LED design. Specifically, the current flip-chip LED design has a distinctive structure of having the electrodes located near the ejector pin contact area, during a die-bonding state of the microfabrication of the flip-chip LED, the flip-chip LED will come into contact with an ejector pin, which may accidentally damage the electrodes while attempting to contact the ejector pin contact area due to the proximity of the electrodes. However, if the electrodes are designed to be placed in a position that circumvents the ejector pin contact area (on the periphery of the flip-chip LED away from the center) to avoid accidental damage, it may cause current flow to spread unevenly which causes uneven light emission in the flip-chip LED.

### SUMMARY

Therefore, an object of the disclosure is to provide a flip-chip light emitting diode (LED) device that can alleviate at least one of the drawbacks of the prior art.

According to one aspect of the disclosure, the flip-chip light emitting diode (LED) device includes an epitaxial structure, a first contact electrode, and a second contact electrode. The epitaxial structure has a first semiconductor layer, an active layer, and a second semiconductor layer that are stacked sequentially. The first contact electrode is disposed on the epitaxial structure and electrically connected to the first semiconductor layer. The second contact electrode is disposed on the epitaxial structure, electrically connected to the second semiconductor layer, and extending in a direction toward the first contact electrode. The second contact electrode includes a first curved extension, a second curved extension, a connecting portion, a first straight extension, and a second straight extension. The first curved extension has two opposite ends. The second curved extension has two opposite ends. The connecting portion has two opposite lateral sides respectively connected to one of the ends of the first curved extension and one of the ends of the second curved extension. The first straight extension is connected to the other one of the ends of the first curved extension distal to the connecting portion. The second straight extension is connected to the other one of the ends of the second curved extension distal to the connecting portion.

According to another aspect of the disclosure, the flip-chip light emitting diode (LED) device includes an epitaxial structure, a first contact electrode and a second contact electrode. The epitaxial structure has a first semiconductor layer, an active layer, and a second semiconductor layer that are sequentially stacked. The first contact electrode is disposed on the epitaxial structure and is electrically connected with the first semiconductor layer. The second contact electrode is disposed on the epitaxial structure and is electrically connected with the second semiconductor layer, and extending in a direction toward the first contact electrode. The second contact electrode includes a first curved extension that has two opposite ends, a second curved extension that has two opposite ends, and a connecting portion that has two opposite lateral sides respectively connected to one of the ends of the first curved extension and one of the ends of the second curved extension. A minimum distance between an end of the first curved extension proximate to the first contact electrode and an end of the second curved extension proximate to the first contact electrode is greater than 70 μm.

### BRIEF DESCRIPTION OF THE DRAWINGS

Other features and advantages of the disclosure will become apparent in the following detailed description of the embodiments with reference to the accompanying drawings, of which:

FIG. 1 is a schematic top view illustrating a first embodiment of a flip-chip light emitting diode (LED) device according to the disclosure;

FIG. 2 is a schematic top view that shows distances amongst components of an epitaxial structure in the first embodiment when the components are projected onto an imaginary plane;

FIG. 3 is a cross-sectional view of the first embodiment taken along line A-A in FIG. 1;

FIGS. 4-9 are schematic top views illustrating various stages of a microfabrication process of the flip-chip LED device;

FIG. 10 is a schematic top view illustrating a second embodiment of the flip-chip LED device;

FIG. 11 is a schematic top view illustrating the third embodiment;

FIG. 12 is a schematic top view illustrating a fourth embodiment of the flip-chip LED device;

FIG. 13 is a schematic top view illustrating distances amongst components of the fourth embodiment when the components are projected onto an imaginary plane.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

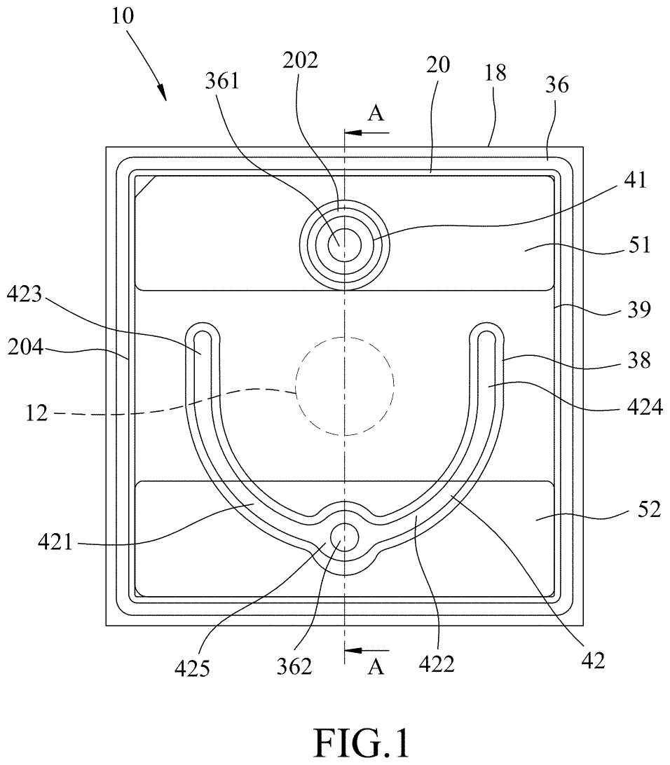

Referring to FIGS. 1 to 3, a first embodiment of a flip-chip light emitting diode (LED) device 10 according to the present disclosure is shown. The flip-chip LED device 10 includes an epitaxial structure 20, a first contact electrode 41, and a second contact electrode 42.

The epitaxial structure 20 is disposed on a substrate 18, and has a first semiconductor layer 21, an active layer 22, and a second semiconductor layer 23 that are stacked sequentially. The substrate 18 may be a transparent substrate, an opaque substrate or a semi-transparent substrate. In some embodiments, where a transparent or semi-transparent substrate is employed, light radiating from the active layer 22 may pass through the substrate 18, i.e., pass from one side of the substrate 18 to reach the other side (the side distal to the epitaxial structure 20). The substrate 18 may be a flat sapphire substrate, a patterned sapphire substrate, a silicon substrate, a silicon carbide substrate, or a gallium nitride substrate.

In some embodiments, the substrate 18 may be a substrate with a patterned surface which may have a single layer or multiple layers of protruding microstructures. The pattern surface includes at least one light extraction layer having a lower refractive index than the substrate 18. The light extraction layer should have a thickness that is greater than half the height of the protruding microstructures to increase light emitting efficiency of the flip-chip LED device 10. The protruding microstructures may have a bullet shape. More preferably, the light extraction layer should have a refractive index lower than 1.6. For example, the light extraction layer may be made of SiO₂. In some embodiments, the substrate 18 may be thinned or removed to create a thin film flip-chip LED device 10.

The epitaxial structure 20 has an ejector pin contact area 12 on its surface which interacts with the ejector pin during a packaging process in the microfabrication of the flip-chip LED device 10. In some embodiments, the ejector pin contact area 12 is a circular region around the centroid of the epitaxial structure 20 as shown in FIG. 1. In this embodiment, the ejector pin contact area 12 has a diameter ranging from 50 μm to 80 μm. During the packaging process of the flip-chip LED device 10 the ejector pin contacts the ejector pin contact area 12 to lift the flip-chip LED device 10 for die-bonding.

The first semiconductor layer 21 may be doped with an N-type dopant. For example, the first semiconductor layer 21 may be a silicon-doped gallium nitride type semiconductor layer. In some embodiments, a buffer layer may be disposed between the first semiconductor layer 21 and the substrate 18. In other embodiments, an adhesion layer (not shown) may be used to connect the epitaxial structure 20 with the substrate 18.

The active layer 22 may have a single quantum well structure or a multi quantum well structure. The wavelength of light generated in the active layer 22 is dependent on the quantum well structure composition and thickness. Notably, by adjusting the quantum well layer composition of the active layer 22, a desired color light, such as an ultra violet light, a blue light, or a green light may be generated.

The second semiconductor layer 23 may be doped with a P-type dopant. For example, the second semiconductor layer 23 may be a magnesium-doped gallium nitride type semiconductor layer.

In this embodiment, the first semiconductor layer 21 and the second semiconductor layer 23 are single-layered structures. However, this is not a limitation of the disclosure, and in other embodiments, the first semiconductor layer 21 and the second semiconductor layer 23 may be multi-layered structures. In some embodiments, the first and second semiconductor layers 21, 23 have multi-layered structures which optionally include superlattice layers. The first and second semiconductor layers 21, 23 may be formed on the substrate 18 via metal-organic chemical vapor deposition (MOCVD) or molecular beam epitaxy (MBE). In other embodiments, the first semiconductor layer 21 is doped with a P-type dopant, and the second semiconductor layer 23 is doped with an N-type dopant.

The first contact electrode 41 and the second contact electrode 42 are disposed on the epitaxial structure 20. The first contact electrode 41 is electrically connected to the first semiconductor layer 21.

The second contact electrode 42 is electrically connected to the second semiconductor layer 23, and is extending in a direction toward the first contact electrode 41. In particular, the second contact electrode 42 includes a connecting portion 425, a first curved extension 421 that has two opposite ends, a first straight extension 423, a second curved portion 422 that has two opposite ends, and a second straight extension 424. The connecting portion 425 has two opposite lateral sides respectively connected to one of the ends of the first curved extension 421 and one of the ends of the second curved extension 422. The first straight extension 423 is connected to the other one of the ends of the first curved extension 421 distal to the connecting portion 425. The second straight extension 424 is connected to the other one of the ends of the second curved extension 422 distal to the connecting portion 425. Referring to FIG. 1, the second electrode 42 is formed in a U-shape, and the positions of the first curved extension 421, the first straight extension 423, the second curved extension 422, and the second straight extension 424 are kept away from the ejector pin contact area 12, so that the ejector pin avoids accidentally damaging the second contact electrode 42 and causing flip-chip abnormality problems. Additionally, unlike LED designs which sacrifice more uniform current spreading to avoid accidental damage by placing the electrodes on the periphery of the LED, the first and second contact electrodes 41, 42 of the present disclosure are designed with the first straight extension 423 connected to the first curved extension 421 and the second straight extension 424 connected to the second curved extension 422 to provide better current spreading and prevent uneven light emission while providing clearance for the ejector pin to contact the ejector pin contact area 12.

In some embodiments, the first contact electrode 41 is in a block shape to prevent a current crowding effect (CCE) and ensure homogeneous distribution of current density, in other words, the first contact electrode 41 does not include any extension portion extending toward the second contact electrode 42.

Referring to FIG. 1, in the first embodiment, the epitaxial structure 20 has four lateral side walls 204, the first and second curved extensions 421, 422 of the second contact electrode 42 respectively extends towards the first contact electrode 41, and respectively approach a left one and a right one of the lateral side walls 204 of the epitaxial structure 20. With reference to a center line (i.e., the same line as the cross sectional line A-A in FIG. 1) parallel to the left and right lateral side walls 204 of the epitaxial structure and passing through the centroid of the epitaxial structure 20, tangent lines that touch at points along the first curved extension 421 intersect the center line at an angle that is no greater than 90 degrees, and the angles of intersection decrease progressively from the connecting portion 425 to the first straight extension 423. Similarly, tangent lines of the second curved extension 422 also intersect the center line at an angle that is no more than 90 degrees, and the angles of intersection decrease progressively from the connecting portion 425 to the second straight extension 424. Therefore, the second contact electrode 42 of the flip-chip LED device 10 is thus designed to circumvent the position of the ejector pin contact area 12 as far as possible, while still allowing the current to flow uniformly in the flip-chip LED device 10.

In this embodiment, the flip-chip LED device 10 has a rectangular shape. However, this is not a limitation of the disclosure, and in other embodiments, the flip-chip LED device 10 may have a circular shape, an ovoid shape, or other polygonal shapes. In some embodiments with a polygonal shape, the epitaxial structure 20 of the flip-chip LED device 10 may have multiple lateral side walls 204.

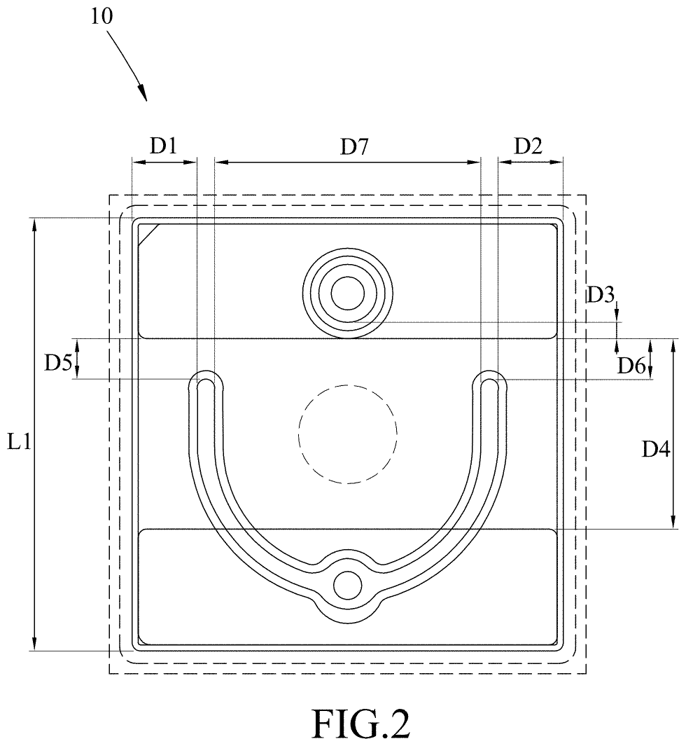

Referring to FIGS. 1 and 2, when the epitaxial structure 20 is projected onto an imaginary plane perpendicular to a stacking direction of the epitaxial structure 20 beneath a bottom of the epitaxial structure 20 and viewed from above a top of the epitaxial structure 20, the lateral side walls 204 form a rectangle. When the second contact electrode 42 is projected onto the imaginary plane and viewed from above the top of the epitaxial structure 20, a minimum distance (D1), that is measured from the first straight extension 423 to a nearest one of the lateral side walls 204 is greater than or equal to 10 μm, and a minimum distance (D2), that is measured from the second straight extension 424 to a nearest one of the lateral side walls 204 is greater than or equal to 10 μm. The minimum distance (D1) and the minimum distance (D2) are preferably greater than or equal to 20 μm. In even more preferred embodiments, the minimum distance (D1) is equal to the minimum distance (D2).

In some embodiments, a minimum distance (D7) between an end of the first straight extension 423 closest to the first contact electrode 41, and an end of the second straight extension 424 closest to the first contact electrode 41 is greater than 70 μm. This helps prevent the ejector pin from damaging the first and second contact electrodes 41, 42 and also ensures homogeneous and uniform current flow. In more preferable embodiments of the present disclosure, the minimum distance (D7) may be 200 μm.

In this embodiment, when the first and second contact electrodes 41, 42 are projected onto the imaginary plane and viewed from above the top of the epitaxial structure 20, an imaginary line connecting a centroid of the connecting portion 425 and a centroid of the first contact electrode 41 is parallel to at least one of the lateral side walls 204. This design ensures the second contact electrode 42 extends towards the first contact electrode 41 while ceding space for the ejector pin contact area 12. However, the disclosure is not thus limited, and in other embodiments, an imaginary line connecting a centroid of the connecting portion 425 and a centroid of the first contact electrode 41 may not be parallel to the left and the right lateral side walls 204. Instead, the imaginary line may intersect the left and right lateral side walls 204 at an angle that is no less than 45° but smaller than 90°. Additionally, the first contact electrode 41 and the second contact electrode 42 may be disposed diagonally, for example, in a square epitaxial structure 20, when the first contact electrode 41 and the second contact electrode 42 are projected onto the imaginary plane and viewed from above the top of the epitaxial structure 20, an imaginary line passing through a centroid of the connecting portion 425 and a centroid of the first contact electrode 41 may run diagonally across the epitaxial structure 20.

In another embodiment, when the second contact electrode 42 is projected onto the imaginary plane and viewed from above the top of the epitaxial structure 20, an imaginary line connecting midpoints of two opposite ones of the lateral side walls 204 intersects the first straight extension 423 and the second straight extension 424. More preferably, the first straight extension 423 and the second straight extension 424 are parallel to each other, and are additionally parallel to at least one of the side walls 204 of the epitaxial structure 20.

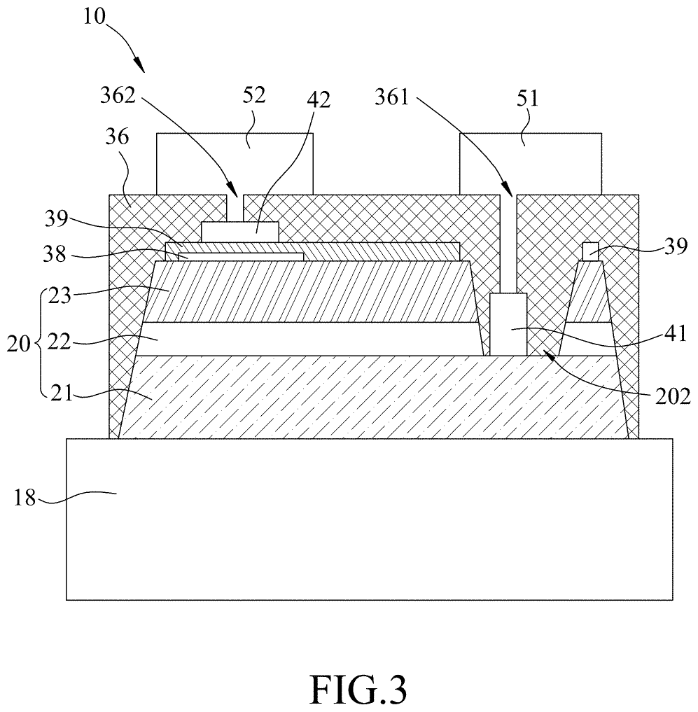

Referring to FIGS. 1 and 3, the flip-chip LED device 10 further includes a through hole 202, a current blocking layer 38, a current spreading layer 39, an insulating layer 36, a first pad 51 and a second pad 52.

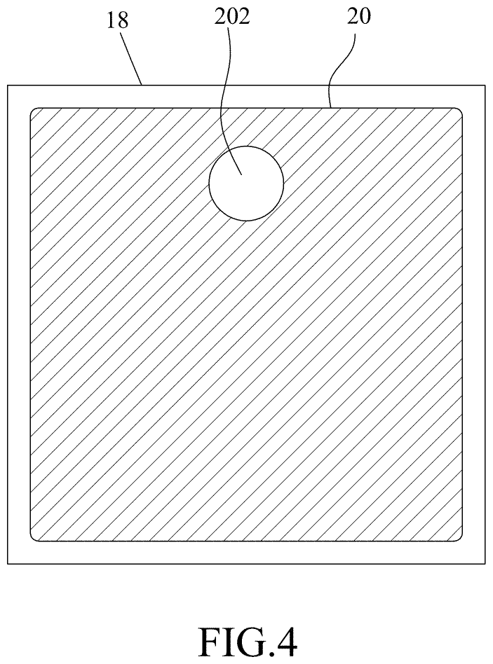

The through hole 202 penetrates the second semiconductor layer 23 and reaches the first semiconductor layer 21 to expose a portion of the first semiconductor layer 21, and the first contact electrode 41 is located within the through hole 202. Therefore, since the through hole 202 penetrates both the active layer 22 and the second semiconductor layer 23, the active layer 22 and the second semiconductor layer 23 have smaller surface areas than the surface area of the first semiconductor layer 21. Referring to FIG. 4, the through hole 202 is preferably in a circular shape when viewed from above the top of the epitaxial structure 20, in more preferred embodiments, the first contact electrode 41 may have the same shape as the through hole 202. It should be noted that there is no limitation on the number of the through holes 202. The flip-chip LED device 10 according to the disclosure includes at least one through hole 202, however, in some embodiments, the flip-chip LED device 10 may include multiple through holes 202 to uniformly spread current. Additionally, in embodiments where the flip-chip LED device 10 has multiple through holes 202, the through holes 202 may be distributed evenly or distributed unevenly according to practical requirements.

Referring to FIGS. 1 and 3, the current blocking layer 38 is disposed between the second semiconductor layer 23 and the second contact electrode 42, and prevents direct downward current flow to the bottom of the second contact electrode 42, thereby reducing current density in the active region 22 below the second contact electrode 42. This reduces light loss due to metal material of the second contact electrode 42, which has light absorbing and light blocking qualities. On the other hand, by virtue of the flip-chip LED device 10 including the current blocking layer 38, current may be directed away from the second contact electrode 42 which may prevent the current from crowding at a region in close proximity to the second contact electrode 42, thereby improving light output of the flip-chip LED device 10. In preferred embodiments, the current blocking layer 38 may be made of the same material as the insulating layer 36. Referring to FIG. 1, the current blocking layer 38 is wider than the second contact electrode 42, when viewed from above the top of the epitaxial structure 20. It is observable that the current blocking layer 38 is at least 2 μm wider at each of two opposite sides of the second contact electrode 42, so that a total width of the current blocking layer 38 is 4 μm larger that of the second contact electrode 42. Preferably, the current blocking layer 38 follows the same contour as the second contact electrode 42.

The current spreading layer 39 is formed on top of the second semiconductor layer 23, covers the current blocking layer 38, and guides current to flow more evenly from the second contact electrode 42 into the second semiconductor layer 23. In some embodiments, the current spreading layer 39 is made of a transparent conductive material or a transparent conducting oxide (TCO) which improves the reliability of the flip-chip LED device 10.

The current spreading layer 39 may be made of a material including but not limited to indium tin oxide (ITO), indium zinc oxide (IZO), indium oxide (InO), tin oxide (SnO), antimony tin oxide (ATO), aluminum zinc oxide (AZO), zinc tin oxide (ZTO), gallium doped zinc oxide (GZO), and tungsten doped indium oxide (IWO), or any combination of the above.

In some embodiments, the current spreading layer 39 may be formed on top of the second semiconductor layer 23 via a deposition process. The deposition process may be chemical vapor deposition (CVD), atomic layer deposition (ALD), other suitable deposition processes, or combinations of the above. However, it should be noted that the present disclosure is not limited to the processes described above.

The insulating layer 36 covers the epitaxial structure 20, the first contact electrode 41, and the second contact electrode 42. More specifically, the insulating layer 36 is covering the second semiconductor layer 23, the first semiconductor layer 21, and the side walls 204 of the epitaxial layer 20, and the coverage of the insulating layer 36 extends to areas of the substrate 18 around the epitaxial layer 20. The insulating layer 36 has a first opening 361, and a second opening 362. The first opening 361 is located above the first contact electrode 41, and the second opening 362 is located above the second contact electrode 42.

The insulating layer 36 provides different effects at the various locations it is covering, for example, the insulating layer 36 covering the side walls 204 of the epitaxial layer 20 may prevent conductive material from contacting the first semiconductor layer 21 and the second semiconductor layer 23, and thereby reduce the likelihood of a short circuit occurring in the flip-chip LED device 10. However, it should be noted that, the location of the insulating layer 36 is not limited to positions described above.

In some embodiments, the insulating layer 36 includes a non-conducting material. In preferred embodiments, the non-conducting material may be an inorganic material such as silicone, or glass, or a dielectric material such as aluminum oxide (AlO), silicon nitride (SiNx), silicon oxide (SiOx), titanium oxide (TiOx), or magnesium fluoride (MgFx). The insulating layer 36 may be made of an insulating material such as silicon dioxide (SiO₂), silicon nitride (SiNx), titanium oxide (TiOx), tantalum oxide (TaOx), niobium oxide (NiOx), and Barium titanate (BaTiO₃), or any combination thereof. In some embodiments, the insulating layer 36 may be a distributed Bragg reflector (DBR) which is formed from alternating layers of two different materials.

The first pad 51 and the second pad 52 are disposed above the insulating layer 36. The first pad 51 is electrically connected to the first contact electrode 41 via the first opening 361, and the second pad 52 is electrically connected to the second contact electrode 42 via the second opening 362. The first pad 51 and the second pad 52 may be rectangular shaped, however, the present disclosure is not limited to such. The first and second pads 51, 52 may be manufactured in the same process and may have a similar structure. For example, the first pad 51 may be an N-type solder pad, and the second pad may be a P-type solder pad.

In some embodiments, when the first contact electrode 41 and the first pad 51 are projected onto the plane and viewed from above the top of the epitaxial structure, a minimum distance (D3) between an outline of the first contact electrode 41 and an outline of the first pad 51 is greater than or equal to 0 μm, which helps to limit the size and decrease the overall dimensions of the flip-chip LED device 10.

In some embodiments, a minimum distance (D4) between the first pad 51 and the second pad 52 is less than ⅓ of the length (L1) of any one of the lateral side walls 204. By spacing apart the first and second pads 51, 52, anti-electrostatic discharge (ESD) capability of the flip-chip LED device 10 may be increased. Preferably, the minimum distance (D4) is less than 200 μm. In preferred embodiments, the minimum distance (D4) may be greater than 30 μm and less than 150 μm, for example, ranging from 60 μm to 100 μm. In other embodiments, when the four lateral side walls 204 and the first and second pads 51, 52 are projected onto the imaginary plane and viewed from above a top of the epitaxial structure the first pad 51 and the second pad 52 both have a width that is less than ⅓ of the length (L1) of any one of the lateral side walls 204.

Referring to FIGS. 1 and 2, in this embodiment, when the second pad 52 and the second contact electrode 42 are projected onto the imaginary plane and viewed from above the top of the epitaxial structure 20, the second pad 52 covers the connecting portion 425, and a portion of each of the first and second curved extensions 421, 422.

In some embodiments, when the first and second contact electrodes 41, 42 are projected onto the imaginary plane and viewed from above the top of the epitaxial structure 20, a minimum distance (D5) between the first straight extension 423 and the first pad 51, and a minimum distance (D6) between the second straight extension 424 and the first pad 51 are both greater than or equal to 20 μm. This minimizes the size of the flip-chip LED device 10 while under the design constraint of needing to situate the first and second electrodes 41, 42 away from the ejector pin contact area 12 to prevent being damaged.

In designing the flip-chip LED device 10, by adjusting the radius of curvature of the first and second curved extensions 421, 422 of the second contact electrode 42, improved current spreading may be achieved. In this embodiment, a radius of curvature of the first curved extension 421 of the second contact electrode 42 and a radius of curvature of the second curved extension 422 of the second contact electrode 42 are both no greater than 50 μm and no less than 25 μm. The radius of curvature of the first and second curved extensions 421, 422 may also be designed with the aim of improving the uniformity of current spreading. For example, the radius of curvature of the first curved extension 421 of the second contact electrode 42 and the radius of curvature of the second curved extensions 422 of the second contact electrode 42 may both be constant; or in other cases the radius of curvature of the first and second contact electrodes 421, 422 may progressively increase along extending directions of the first and second curved extensions 421, 422 (i.e., progressively increasing from the connecting portion 425 towards the first and second straight extensions 423, 424).

In this embodiment, a distance between an end of the first curved extension 421 and an end of the second curved extension 422 is not greater than twice the radius of curvature of the first curved extension 421, and this distance may be equal to the minimum distance (D7).

In designing the flip-chip LED device 10, by regulating the length of the first straight extension 423 and the length of the second straight extension 423, current spreading in the flip-chip LED device 10 may be improved. Additionally, saturation current and electrostatic discharge (ESD) prevention of the flip-chip LED device 10 may be enhanced. The length of the first straight extension 423 and the length of the second straight extension 423 should be designed according to practical requirements.

In this embodiment, the flip-chip LED device 10 has a rectangular shape with an aspect ratio in a range of 1:1 to 1:1.5. Preferably, the size of the flip-chip LED device is less than 15 mil*15 mil (width*length).

Referring to FIG. 4, in the microfabrication process of the flip-chip LED device 10, a first semiconductor layer 21, an active layer 22, and a second semiconductor layer 23 are stacked sequentially on the substrate 18 to form the epitaxial structure 20. Next, etching is carried out from the surface of the second semiconductor layer 23 to the first semiconductor layer 21 to form the through hole 202. Optionally, border regions of the epitaxial structure 20 are removed to uncover a part of the substrate 18 and to thereby facilitate subsequent processing steps, such as wafer dicing, for obtaining flip-chip LED devices 10 off the wafer.

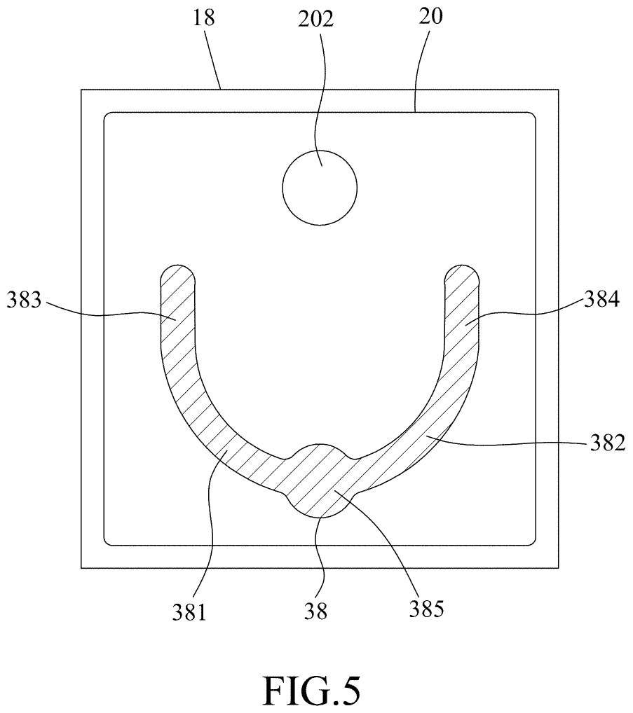

Referring to FIG. 5, in the next stage, the current blocking layer 38 is formed on top of the second semiconductor layer 23 to block vertical current flow between the second contact electrode 42 and the second semiconductor layer 23. Preferably, the current blocking layer 38 may include an initial portion 385, a first curved extension 381, a first straight extension 383, a second curved extension 382, and a second straight extension 384. As illustrated in FIG. 5, left and right sides of the initial portion 385 are respectively connected to the first curved extension 381 and the second curved extension 382. The first straight extension 383 is connected to an end of the first curved extension 381 distal to said initial portion 385, and the second straight extension 384 is connected to an end of the second curved extension 382 distal to the initial potion 385, thereby causing the current blocking layer 38 to form a U-shape. Additionally, the first curved extension 381, the first straight extension 383, the second curved extension 382, and the second straight extension 384 are designed to be kept away from the ejector pin contact area 12. Additionally, the radius of curvature of the first curved extension 381 of the current blocking layer 38 and the radius of curvature of the second curved extension 382 of the current blocking layer 38 may both be constant, may both be no smaller than 20 μm, or no greater than 60 μm.

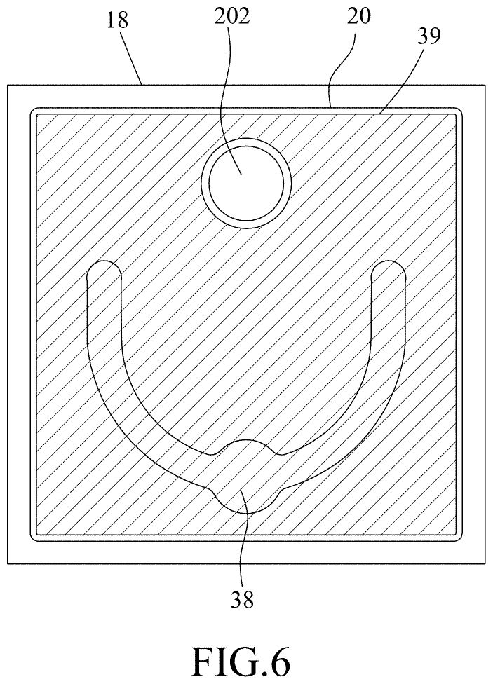

Referring to FIG. 6, subsequently, the current spreading layer 39 is formed on top of the current blocking layer 38, and used to spread current so as to increase the reliability of the flip-chip LED device 10. The current spreading layer 39 is formed with an opening that is larger than the through hole 202, and that reveals the second semiconductor layer 23. The surface area of the current spreading layer 39 may be smaller than the surface area of the second semiconductor layer 23.

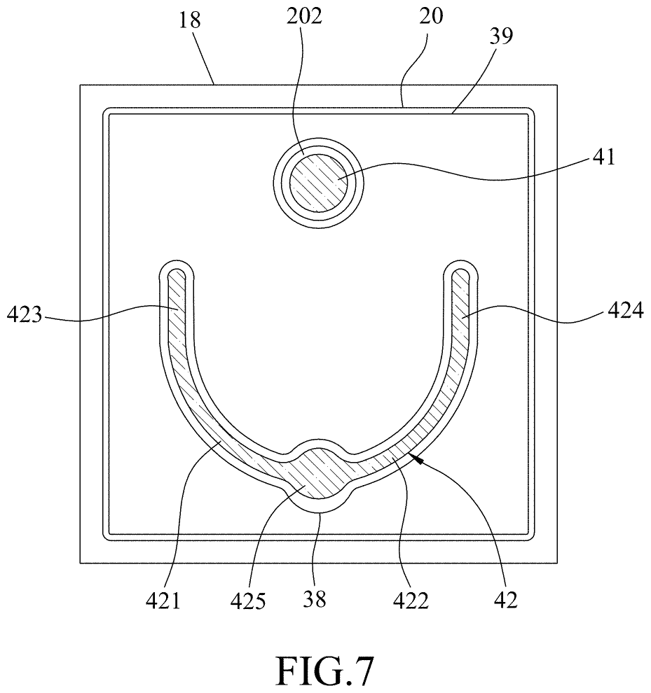

Referring to FIG. 7, the first contact electrode 41 is then formed on top of the first semiconductor layer 21 in the through hole 202, while the second contact electrode 42 is formed on top of the current blocking layer 38, and the surface area of the current blocking layer 38 is larger than the surface area of the second contact electrode 42. The second contact electrode 42 extends in a direction toward the first contact electrode 41, and includes the connecting portion 425, the first curved extension 421 that has two opposite ends, the first straight extension 423, the second curved extension 422 that has two opposite ends, and the second straight extension 424. Referring to FIG. 7, the connecting portion 425 has two opposite lateral sides respectively connected to one of the ends of the first curved extension 421 and one of the ends of the second curved extension 422. The first straight extension 423 connects to the other one of the ends of the first curved extension 421 distal to the connecting portion 425. The second straight extension 424 is connected to the other one of the ends of the second curved extension 422 distal to the connecting portion 425. The second contact electrode 42 is formed in a U-shape.

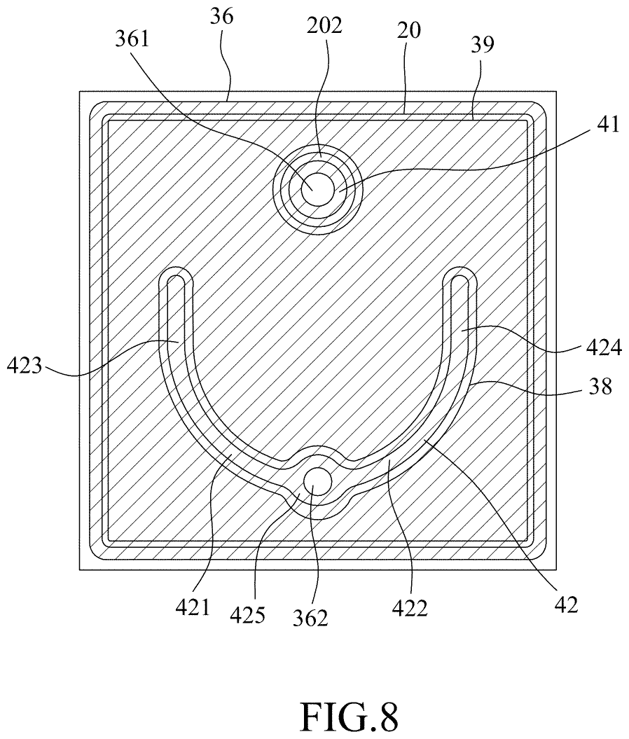

Referring to FIG. 8, subsequently the insulating layer 36 is formed to cover the epitaxial structure 20, partially cover the first contact electrode 41, partially cover the second contact electrode 42, the current spreading layer 39, the side walls 204 of the epitaxial layer 20, and a portion of the surface of the substrate 18 around the epitaxial structure 20. The insulating layer 36 has a first opening 361 that is located above the first contact electrode 41 in the through hole 202 to partially reveal the first contact electrode 41, and a second opening 362 that is located above the second contact electrode 42 to partially reveal the second contact electrode 42.

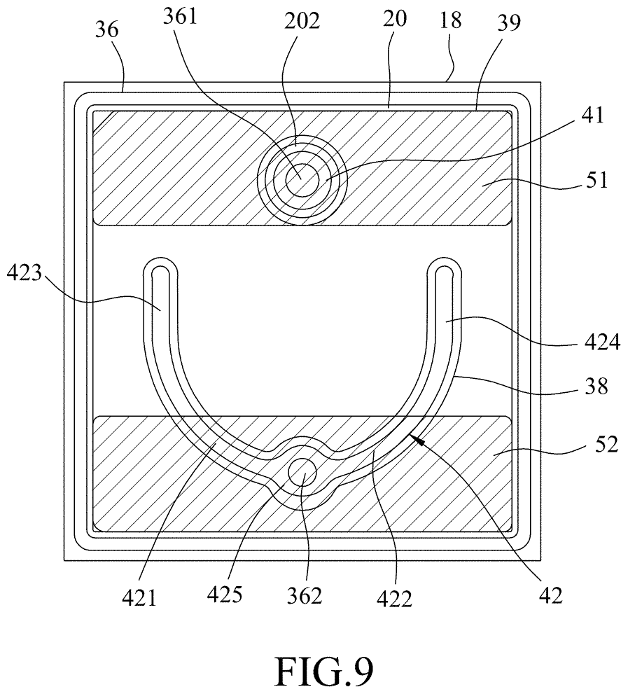

Referring to FIG. 9 a first pad 51 and a second pad 52 are disposed above the insulating layer 36 and spaced apart from each other. The first pad 51 is electrically connected to the first contact electrode 41 via the first opening 361, and the second pad 52 is electrically connected to the second contact electrode 42 via the second opening 362.

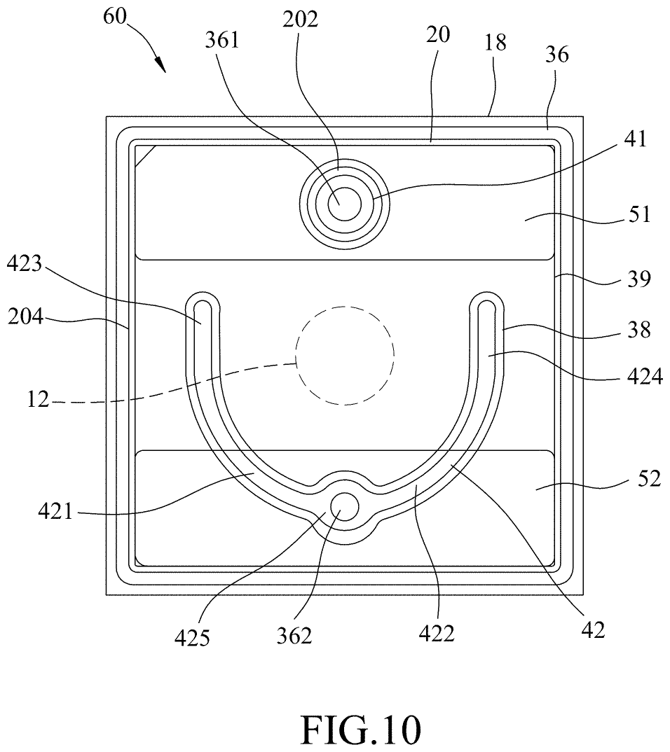

Referring to FIG. 10, a second embodiment of the flip-chip LED device 60 is shown. The second embodiment is similar to the first embodiment. However, the second embodiment of the flip-chip LED device 60 is different from the first embodiment in that, compared to the through hole 202 in the first embodiment, the through hole 202 in this embodiment is more proximate to a top one of the lateral side walls 204 situated away from the second electrode 42, to prevent the first electrode 41 from being too close to the second electrode 42.

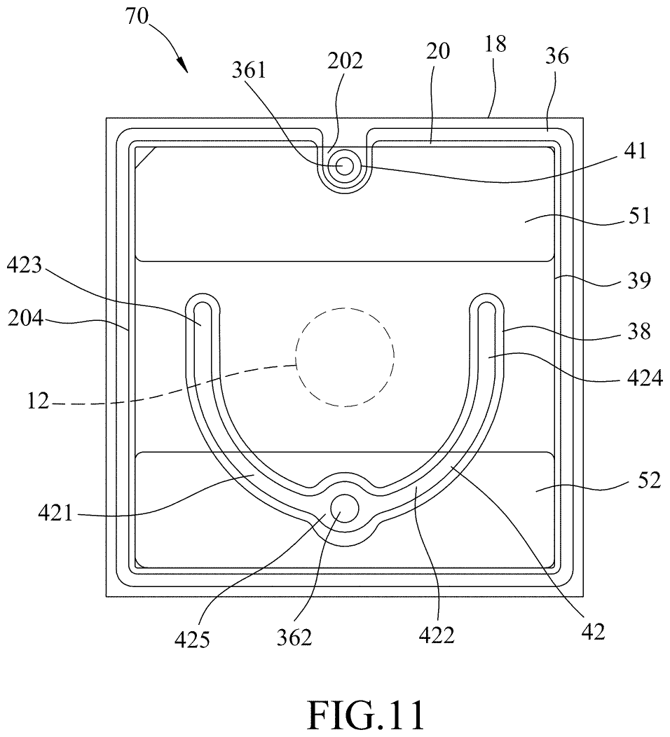

Referring to FIG. 11, showing a third embodiment of the flip-chip LED device 70, where the through hole 202 is in a U-shape, and an outer surface of one of the lateral side walls 204 of the epitaxial structure 20 is opened in an outward direction. In other aspects the third embodiment is similar to the first embodiment and further description of the similar aspects are omitted.

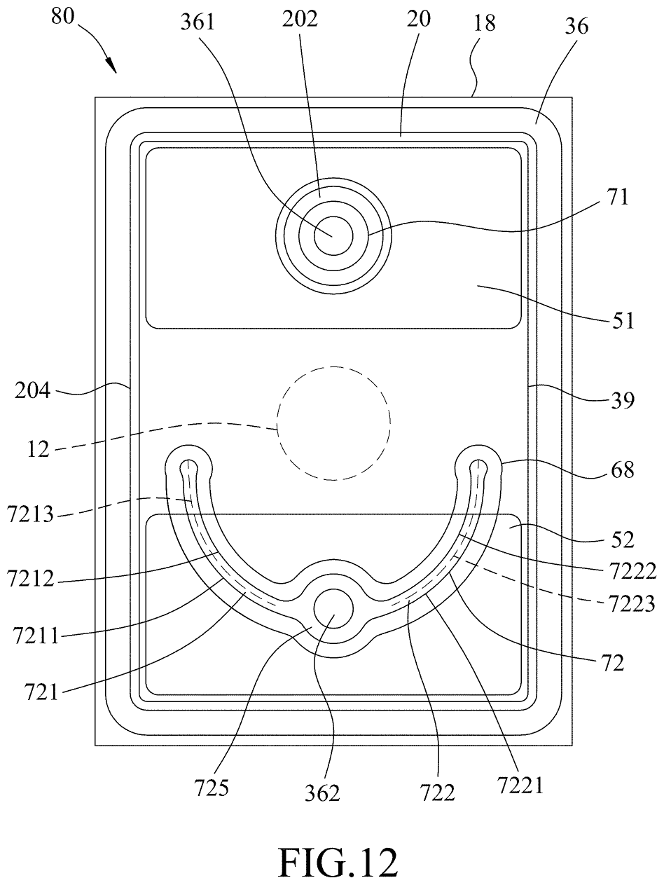

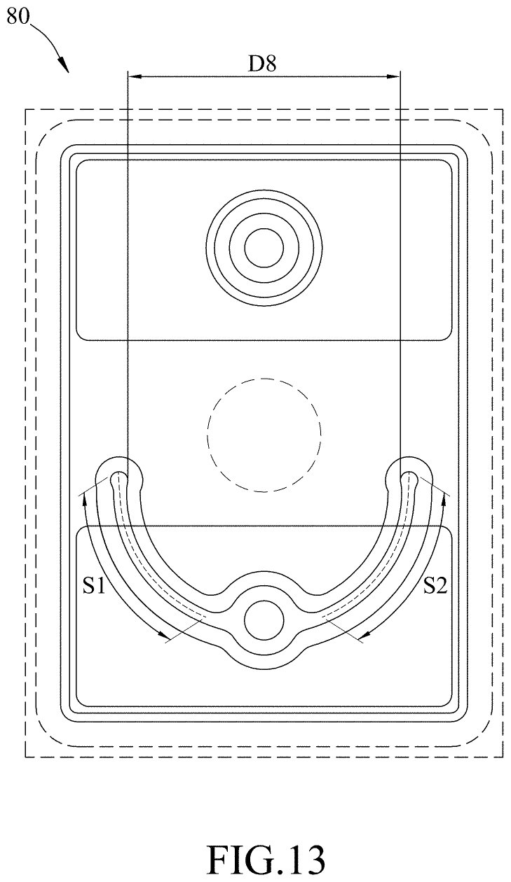

Referring to FIGS. 12 and 13, a fourth embodiment of the flip-chip LED device 80 is shown. The fourth embodiment of the flip-chip LED device 80 is similar to the first embodiment of the flip-chip LED device 10, except that the shape of the fourth embodiment is rectangular and elongated compared to the first embodiment, and in the fourth embodiment, the second contact electrode 72 of the flip-chip LED device 80 does not include the first straight extension 423 and the second straight extension 424 of the first contact electrode 42 in the first embodiment. The second contact electrode 72 of the fourth embodiment includes a connecting portion 725, a first curved extension 721 that has two opposite ends, and a second curved extension 722 that has two opposite ends. The connecting portion 725 has two opposite lateral sides respectively connected to one of the ends of the first curved extension 721 and one of the ends of the second curved extension 722 so that the second contact electrode 72 of the flip-chip LED device 80 is semi-circular. In the fourth embodiment of the flip-chip LED device 80, the current blocking layer 68 corresponds to the shape of the second contact electrode 72 above it. It should be noted, that the fourth embodiment is similar to the first embodiment in all other aspects, the details of which are omitted for the sake of brevity.

The rectangular flip-chip LED device 80 has a size of about 9 mil*12 mil. The fourth embodiment may have good current spreading characteristics by only including the first and second curved extensions 721, 722. In addition, the first and second contact electrodes 71, 72 that are near the ejector pin contact area 12 can be prevented from being damaged by the ejector pin.

In the fourth embodiment, a minimum distance (D8) between an end of the first curved extension 721 proximate to the first contact electrode 71 and an end of the second curved extension 722 proximate to the first contact electrode 71 is greater than 70 μm. In other words, the distance between the ends of the first and second curved extensions 721, 722 is greater than 70 μm.

Referring to FIGS. 12 and 13, the first curved extension 721 has an outer convexed edge 7211 and an inner concaved edge 7212, and a medial line 7213 positioned mid-way between the outer convexed edge 7211 and the inner concaved edge 7212, and conforming to the curvature of the first curved extension 721 (shown as a dotted line in FIG. 12). The first curved extension 721 has an arc length (S1) that is the length of the medial line 7213 of the first curved extension 721. The second curved extension 722 has an outer convexed edge 7221 and an inner concaved edge 7222, and a medial line 7223 positioned mid-way between the outer convexed edge 7221 and the inner concaved edge 7222, and conforming to the curvature of the second curved extension 722 (shown as a dotted line in FIG. 12). The second curved extension 722 has a second arc length (S2) that is the length of the medial line 7223 of the second curved extension 722.

In order to obtain a better current spreading effect and to prevent damage from the ejector pin, the arc length (S1) of the first curved extension 721 and the second arc length (S2) of the second curved extension 722 are both greater than n/5 times the minimum distance (D8), and are both less than n/3 times the minimum distance (D8). More preferably, the arc length (S1) of the first curved extension 721 is equal to second arc length (S2) of the second curved extension 722, and roughly equal to n/4 of the minimum distance (D8). In some embodiments, the minimum distance (D8) may be equal to the minimum distance (D7) (see FIG. 2).

In preferred embodiments, the medial line 7213 of the first curved extension 721 and the medial line 7223 of the second curved extension 722 are both part of a first imaginary circle; the outer convexed edge 7211 of the first curved extension 721 and the outer convexed edge 7221 of the second curved extension 722 are both part of a second imaginary circle; and the inner concaved edge 7212 of the first curved extension 721 and the inner concaved edge 7222 of the second curved extension 722 are both part of a third imaginary circle. The first, second, and third imaginary circles are concentric circles, and have the same center.

Additional embodiments of the disclosure are related to light emitting devices (not shown) which adapt the flip-chip LED devices (10, 60, 70, 80) of the embodiments described hereinbefore.

More preferably, the flip-chip LED devices 10, 60, 70, 80 may be employed in display panels such as a backlit monitor, or an RGB monitor. When employed as such, several hundred to several thousand of the flip-chip LED devices 10, 60, 70, 80 are mounted to, or packaged on a base panel, which forms a backlight panel of the backlit monitor or a light source of the RGB monitor. It should be additionally noted that due to minute variations in the microfabrication process, the straight extensions (such as the first and second straight extensions 423, 424 of the second contact electrode 42 and the first and second straight extensions 383, 384 of the current blocking layer 38) may not extend in a perfectly straight line, but instead may warp or protrude slightly. By analogy, the curvature of the curved extensions (such as the first and second curved extensions 421, 422, 721, 722, of the second contact electrode 42, 72 and the first and second curved extensions 381, 382 of the current blocking layer 38) may also deviate from a perfectly circular track and have slight protrusions or warping.

In summary of the above, in the flip-chip LED device 10, 60, 70, 80 disclosed in the present disclosure, by virtue of including the second contact electrode 42, 72 that includes the first and second curved extensions 421, 422, 721, 722, and that, in some of the embodiments, includes the first and second straight extensions 423, 424, the current spreading characteristics of the flip-chip LED device 10, 60, 70, 80 is improved, and the ejector pin contact area 12 is left unobstructed so that the ejector pin may be prevented from accidentally damaging the first and second contact electrodes 41, 42, 71, 72. Therefore, the reliability and the brightness of the flip-chip LED device 10, 60, 70, 80 is improved.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A flip-chip light emitting diode (LED) device comprising:
an epitaxial structure having a first semiconductor layer, an active layer, and a second semiconductor layer that are stacked sequentially;
a first contact electrode disposed on said epitaxial structure and electrically connected to said first semiconductor layer; and
a second contact electrode disposed on said epitaxial structure, electrically connected to said second semiconductor layer, extending in a direction toward said first contact electrode, and including
a first curved extension that has two opposite ends,
a second curved extension that has two opposite ends,
a connecting portion that has two opposite lateral sides respectively connected to one of said ends of said first curved extension and one of said ends of said second curved extension,
a first straight extension that connects to the other one of said ends of said first curved extension distal to said connecting portion, and
a second straight extension connected to the other one of said ends of said second curved extension distal to said connecting portion.

2. The flip-chip LED device as claimed in claim 1, wherein:
said flip-chip LED device has a rectangular shape;
said epitaxial structure has four lateral side walls;
when said epitaxial structure is projected onto an imaginary plane perpendicular to a stacking direction of said epitaxial structure beneath a bottom of said epitaxial structure and viewed from above a top of said epitaxial structure, said lateral side walls forms a rectangle.

3. The flip-chip LED device as claimed in claim 2, wherein, when said second contact electrode is projected onto said imaginary plane and viewed from above the top of said epitaxial structure, a minimum distance, that is measured from said first straight extension to a nearest one of said lateral side walls is greater than or equal to 10 μm.

4. The flip-chip LED device as claimed in claim 2, wherein, when said second contact electrode is projected onto said imaginary plane and viewed from above the top of said epitaxial structure, a minimum distance, that is measured from said second straight extension to a nearest one of said lateral side walls, is greater than or equal to 10 μm.

5. The flip-chip LED device as claimed in claim 2, wherein:
when said second contact electrode is projected onto said imaginary plane and viewed from above the top of said epitaxial structure, a minimum distance that is measured from said first straight extension to a nearest one of said lateral side walls of said epitaxial structure is equal to a minimum distance that is measured from said second straight extension to a nearest one of said lateral side walls of said epitaxial structure.

6. The flip-chip LED device as claimed in claim 2, wherein:
a minimum distance between an end of said first straight extension closest to said first contact electrode and an end of said second straight extension closest to said first contact electrode is greater than 70 μm.

7. The flip-chip LED device as claimed in claim 2, wherein, when said first and second contact electrodes are projected onto said imaginary plane and viewed from above the top of said epitaxial structure, an imaginary line connecting a centroid of said connecting portion and a centroid of said first contact electrode is parallel to at least one of said lateral side walls.

8. The flip-chip LED device as claimed in claim 2, wherein, when said second contact electrode is projected onto said plane and viewed from above the top of said epitaxial structure, an imaginary line connecting midpoints of two opposite ones of said lateral side walls intersects said first straight extension and said second straight extension.

9. The flip-chip LED device as claimed in claim 1, further comprising an insulating layer, a first pad and a second pad disposed above said insulating layer, said insulating layer covering said epitaxial structure, and has a first opening that is located above said first contact electrode, and a second opening that is located above said second contact electrode, said first pad being electrically connected to said first contact electrode via said first opening, and said second pad being electrically connected to said second contact electrode via said second opening.

10. The flip-chip LED device as claimed in claim 9, wherein, when said first contact electrode and said first pad are projected onto said plane and viewed from above the top of said epitaxial structure, a minimum distance between an outline of said first contact electrode and an outline of said first pad is greater than or equal to 0 μm.

11. The flip-chip LED device as claimed in claim 9, wherein a minimum distance between said first pad and said second pad is less than 200 μm.

12. The flip-chip LED device as claimed in claim 9, wherein:
said epitaxial structure has four lateral side walls; and
when said four lateral side walls and said first and second pads are projected onto an imaginary plane perpendicular to a stacking direction of said epitaxial structure beneath a bottom of said epitaxial structure and viewed from above a top of said epitaxial structure, said first pad and said second pad both have a width that is less than ⅓ of the length of any one of said lateral side walls.

13. The flip-chip LED device as claimed in claim 9, wherein, when said second pad and said second contact electrode are projected onto said imaginary plane and viewed from above the top of said epitaxial structure, said second pad covers said connecting portion, and a portion of each of said first and second curved extensions.

14. The flip-chip LED device as claimed in claim 9, wherein:
when said first and second contact electrodes are projected onto said imaginary plane and viewed from above the top of said epitaxial structure, a minimum distance between said first straight extension and said first pad and a minimum distance between said second straight extension and said first pad are both greater than or equal to 20 μm.

15. The flip-chip LED device as claimed in claim 1, wherein a radius of curvature of said first curved extension of said second contact electrode and a radius of curvature of said second curved extension of said second contact electrode are both not greater than 50 μm and not less than 25 μm.

16. The flip-chip LED device as claimed in claim 15, wherein a distance between an end of said first curved extension and an end of said second curved extension is not greater than twice the radius of curvature of the first curved extension.

17. The flip-chip LED device as claimed in claim 1, wherein:
said epitaxial structure has multiple lateral side walls;
when said multiple lateral side walls and said second contact electrode are projected onto an imaginary plane perpendicular to a stacking direction of said epitaxial structure beneath a bottom of said epitaxial structure and viewed from above a top of said epitaxial structure, said first straight extension and said second straight extension are both parallel to at least one of said lateral side walls.

18. The flip-chip LED device as claimed in claim 1, wherein said flip-chip LED device has a rectangular shape with an aspect ratio in a range of 1:1 to 1:1.5.

19. A flip-chip light emitting diode (LED) device comprising:
an epitaxial structure having a first semiconductor layer, an active layer, and a second semiconductor layer that are sequentially stacked;
a first contact electrode disposed on said epitaxial structure and electrically connected with said first semiconductor layer; and
a second contact electrode disposed on said epitaxial structure, electrically connected with said second semiconductor layer, and extending in a direction toward said first contact electrode, and including
a first curved extension that has two opposite ends,
a second curved extension that has two opposite ends, and
a connecting portion that has two opposite lateral sides respectively connected to one of said ends of said first curved extension and one of said ends of said second curved extension; and
wherein, a minimum distance between an end of said first curved extension proximate to said first contact electrode and an end of said second curved extension proximate to said first contact electrode is greater than 70 μm.

20. The flip-chip LED device as claimed in claim 19, wherein a first arc length of said first curved extension and a second arc length of said second curved extension are both greater than n/5 times said minimum distance and are both less than n/3 times said minimum distance.
